(19) United States
(12) Patent Application Publication
(10) Pub. No.: US 2025/0321126 A1
(43) Pub. Date: Oct. 16, 2025

(54) METHOD AND DEVICE FOR CONDITIONING A MEASUREMENT SIGNAL

(71) Applicants: SKF Magnetic Mechatronics, Saint-Marcel (FR); SKF Canada Limited, Scarborough (CA)

(72) Inventors: Nicholas FALCONAR, Calgary (CA); Lakdar SADI-HADDAD, Nogent sur Marne (FR); Jinyi XIE, Hébécourt (FR); Gregory W. SMITH, Calgary (CA); Udell SO, Calgary (CA)

(21) Appl. No.: 19/169,106

(22) Filed: Apr. 3, 2025

(30) Foreign Application Priority Data
Apr. 11, 2024 (FR) FR2403756

(51) Int. Cl. G01D 5/244; G01D 5/20

(52) U.S. Cl. CPC G01D 5/244; G01D 5/20

(57) ABSTRACT

A device for conditioning a measurement signal supplied by an inductive position sensor (7, 8) for a rotor (3) of an electric machine (1) supported by at least one active magnetic bearing (4). The inductive position sensor (7, 8) measures a displacement of the rotor (3) and is supplied by an alternating voltage source (10a) supplying a sinusoidal voltage at a predetermined constant frequency. The device includes a sampler (15) and a first means (16). The sampler (15) samples first and second samples of the measurement signal at different times. The first means breaks down the measurement signal into a sum of a sine function and a cosine function from the first and second samples of the measurement signal.

### CROSS-REFERENCE TO RELATED APPLICATION

This application claims priority to French Application No. FR2403756, filed Apr. 11, 2024, the entirety of which is hereby incorporated by reference.

### FIELD

The present disclosure relates to electrical machines comprising a rotor supported by magnetic bearings and, in particular, to the processing of a signal supplied by an inductive position sensor of such an electrical machine.

The present disclosure relates more particularly to a method for conditioning a measurement signal supplied by an inductive position sensor of the rotor of such an electrical machine.

### BACKGROUND

Magnetic bearings are used in various rotary machines such as electric motors, compressors, turbines, or the like, in order to maintain the axial and/or radial positions of a rotor by means of magnetic fields acting on the rotor of the machine.

Inductive position sensors are used in magnetic bearing controllers (MBC) to measure the position of the rotor.

The measurements supplied by the position sensors are used to control the magnetic bearings.

An inductive position sensor comprises two inductive elements connected in series.

An alternating supply voltage is applied to the ends of the inductive elements.

A displacement of the rotor causes a variation in the air gap generating a variation in the inductance of the inductive elements.

A modulated alternating voltage is measured between the two inductive elements, representing the variation in the inductance.

The displacement of the rotor is determined from the alternating voltage measured between the two inductive elements.

When the rotor is centred in the magnetic bearings and the displacement of said rotor is zero, the inductive components of the two inductive elements are equal, and the alternating voltage supplied by the sensor has a zero amplitude.

Displacement of the rotor in one direction along an axis causes a proportional increase in the amplitude of the alternating voltage emitted by the sensor. The displacement of the rotor in the opposite direction along the axis causes a proportional increase in the amplitude of the alternating voltage supplied by the sensor and phase-shifted through 180°.

In practice, the inductive elements comprise parasitic resistive elements such that a phase shift appears between the supply voltage and the modulated alternating voltage at the output of the inductive sensor.

The phase shift or quadrature error makes it difficult to measure the alternating voltage supplied by the sensor and prevents the determination of the position of the rotor with sufficient precision to control the magnetic bearings.

In order to eliminate the quadrature error, the modulated alternating voltage is demodulated and filtered in particular by a low-pass filter to determine the DC component of the signal representing the position of the rotor. The low-pass filter creates a phase delay which degrades the ability to control the rotor position.

In addition, the low-pass filter removes the quadrature component of the alternating voltage supplied by the sensor which includes information enabling the position of the rotor to be determined more accurately.

### SUMMARY

The present disclosure therefore aims to overcome some or all of these disadvantages.

According to one aspect, the present disclosure relates to a method for conditioning a measurement signal supplied by an inductive position sensor for a rotor of an electrical machine supported by at least one active magnetic bearing.

The inductive position sensor measures a displacement of the rotor and is powered by an alternating voltage source supplying a sinusoidal supply voltage having a predetermined constant period.

The method comprises:
sampling the measurement signal at a first sampling time to determine a first sample of the measurement signal,
sampling the measurement signal at a second sampling time to determine a second sample of the measurement signal, the second sampling time being separated from the first sampling time by a duration equal to one quarter of the predetermined constant period of the sinusoidal supply voltage, and
breaking down the measurement signal into a sum of a sine function and a cosine function from the first and second samples of the measurement signal and a predetermined phase shift between the phase of the sinusoidal supply voltage and the phase of a sampling signal associated with the first and second sampling times.

The conditioning method makes it possible to break down the measurement signal into an in-phase component corresponding to the sine function and into a quadrature component corresponding to the cosine function.

The determination of the in-phase and quadrature components is carried out in a simple manner, without the addition of processing means or a control loop.

The first sampling time is preferably chosen when the sinusoidal supply voltage is zero and the second sampling time is chosen when the absolute value of the sinusoidal supply voltage is maximum, and the measurement signal is broken down into a signal Sm according to the following equation:

$$Sm ( t ) = c . sin ( ω t + θ ) = a . sin ( ω t ) + b . cos ( ω t )$$

where sin is the trigonometric sine function, cos is the trigonometric cosine function, t is time, ω is such that

$$ω = \frac{2 π}{T} ,$$

T is the predetermined constant period, a is a first coefficient, and b is a second coefficient, a, b, c being real numbers, and θ is a constant.

The breakdown of the measurement signal comprises determining the first coefficient a and the second coefficient b from the first sample of the measurement signal associated with the first sampling time and from the second sample of the measurement signal associated with the second sampling time, the first and second coefficients a and b being such that:

$$a = {x}_{90 °}$$

$$b = {x}_{0 °}$$

Advantageously, the second sampling time is chosen a quarter of a period after the first sampling time, and the measurement signal is broken down into a signal Sm according to the following equation:

$$Sm ( t ) = c . sin ( ω t + θ ) = a . sin ( ω t ) + b . cos ( ω t )$$

where sin is the trigonometric sine function, cos is the trigonometric cosine function, t is time, ω is such that

$$ω = \frac{2 π}{T} ,$$

T is the predetermined constant period, a is a first coefficient, and b is a second coefficient, a, b, c being real numbers, and θ is a constant.

The breakdown of the measurement signal comprises determining the first coefficient a and the second coefficient b from the first sample of the measurement signal associated with the first sampling time and from the second sample of the measurement signal associated with the second sampling time, the first and second coefficients a and b being such that:

$$a = \{ \begin{matrix}cos ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ cos ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$

$$b = \{ \begin{matrix}sin ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ sin ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$

tan⁻¹ being the trigonometric arc tangent function and φ being the predetermined phase shift between the first sampling time and the sinusoidal supply voltage, xₜ₁₀ being the first sample of the measurement signal and xₜ₂₀ being the second sample.

According to another aspect, the present disclosure also relates to a device for conditioning a measurement signal supplied by an inductive position sensor for a rotor of an electric machine supported by at least one active magnetic bearing.

The inductive position sensor measures a displacement of the rotor and is powered by an alternating voltage source supplying a sinusoidal supply voltage having a predetermined constant period.

The device comprises:
a sampler configured to sample the measurement signal at a first sampling time in order to determine a first sample of the measurement signal and to sample the measurement signal at a second sampling time in order to determine a second sample of the measurement signal, the second sampling time being separated from the first sampling time by a duration equal to one quarter of the predetermined constant period of the sinusoidal supply voltage, and
first means configured to break down the measurement signal into a sum of a sine function and a cosine function from the first and second samples of the measurement signal, and a predetermined phase shift between the phase of the sinusoidal supply voltage and the phase of a sampling signal associated with the first and second sampling times.

The first means are preferably configured to break down the measurement signal into a signal Sm according to the following equation:

$$Sm ( t ) = c . sin ( ω t + θ ) = a . sin ( ω t ) + b . cos ( ω t )$$

where sin is the trigonometric sine function, cos is the trigonometric cosine function, t is time, ω is such that

$$ω = \frac{2 π}{T} ,$$

T is the predetermined constant period, a is a first coefficient, and b is a second coefficient, a, b, c being real numbers, and θ is a constant.

The first means further being configured to determine the first coefficient a and the second coefficient b from the first sample of the measurement signal associated with the first sampling time and from the second sample of the measurement signal associated with the second sampling time, the first and second coefficients a and b being such that:

$$a = {x}_{90 °}$$

$$b = {x}_{0 °}$$

The first means are advantageously configured to break down the measurement signal into a signal Sm according to the following equation:

$$Sm ( t ) = c . sin ( ω t + θ ) = a . sin ( ω t ) + b . cos ( ω t )$$

where sin is the trigonometric sine function, cos is the trigonometric cosine function, t is time, ω is such that

$$ω = \frac{2 π}{T} ,$$

T is the predetermined constant period, a is a first coefficient, and b is a second coefficient, a, b, c being real numbers, and θ is a constant.

The first means further being configured to determine the first coefficient a and the second coefficient b from the first sample of the measurement signal associated with the first sampling time and the second sample of the measurement signal associated with the second sampling time, the first and second coefficients a and b being such that:

$$a = \{ \begin{matrix}cos ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ cos ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$

$$b = \{ \begin{matrix}sin ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ sin ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$

tan⁻¹ being the trigonometric arc tangent function and φ being the predetermined phase shift between the first sampling time and the sinusoidal supply voltage, xₜ₁₀ being the first sample of the measurement signal and xₜ₂₀ being the second sample.

The device preferably further comprises a processing unit configured to control the sampler such that the phase shift is equal to a predetermined target value.

According to another further aspect, the present disclosure also relates to a measurement assembly comprising a conditioning device as defined above, and an inductive position sensor connected to the conditioning device.

The inductive position sensor is advantageously a radial inductive position sensor configured to measure the radial position of the rotor.

The inductive position sensor is preferably an axial inductive position sensor configured to measure the axial position of the rotor.

### BRIEF DESCRIPTION OF THE DRAWINGS

Other advantages and characteristics of the present disclosure will become evident from an examination of the detailed descriptions of the embodiments, which are in no way limiting. The attached drawings are described below:

FIG. 1 shows schematically a machine according to the present disclosure;

FIG. 2 shows schematically an example of a measurement assembly according to the present disclosure;

FIGS. 3 and 4 show schematically a first example of a method for conditioning a measurement signal according to the present disclosure; and

FIGS. 5 and 6 show schematically a second example of a method for conditioning a measurement signal according to the present disclosure.

### DETAILED DESCRIPTION

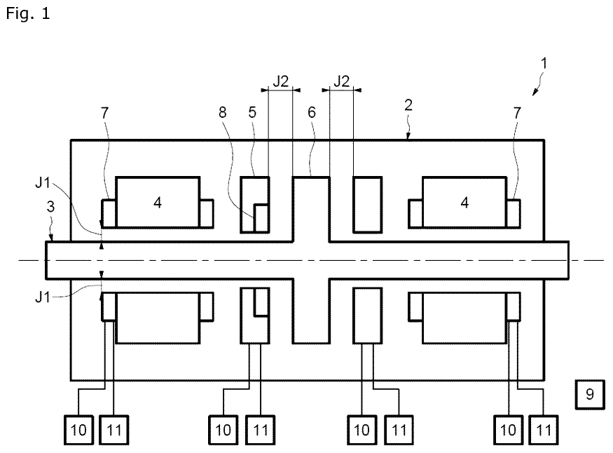

Reference is made to FIG. 1 which shows schematically a partial longitudinal cross section of a machine 1.

The machine 1 comprises a housing 2, a rotor 3 supported in the housing 2 by two radial active magnetic bearings 4 and an axial active bearing 5.

The radial active magnetic bearings 4 radially surround the rotor 3.

The rotor 3 further comprises a disc 6 surrounded axially by the axial active bearing 5.

The machine 1 further comprises two inductive position sensors 7 for measuring the radial position of the rotor 3, and two inductive position sensors 8 arranged on either side of the disc 5 for measuring the axial position of the rotor 3.

The measurements supplied by the inductive position sensors 6 measuring the radial position of the rotor 3 and the measurements supplied by the inductive position sensors 8 measuring the axial position of the rotor 3 are transmitted to control means 9 of the magnetic bearings 4 comprising, for example, a processing unit.

The machine 1 further comprises a plurality of supply circuits 10 of the sensors 7, 8 and a plurality of conditioning devices 11.

Each supply circuit 10 is connected to a sensor 7, 8 to supply power to said sensor 7, 8.

The supply circuit 10 can be located outside the machine 1 as shown.

In one variant, the supply circuit 10 is located inside the machine 1.

Each conditioning device 11 is connected to a sensor 7, 8 for conditioning a measurement signal supplied by said sensor 7, 8.

The conditioning device 11 can be located outside the machine 1 as shown.

In one variant, the conditioning device 11 is located inside the machine 1.

A sensor 7, 8, the supply circuit 10 connected to said sensor 7, 8 and the conditioning device 11 connected to said sensor 6, 7 form a measurement assembly.

It is assumed that the rotor 3 is separated from the inductive position sensors 7 measuring the radial displacement of the rotor 3 by an air gap J₁ and that the disc 6 of the rotor 3 is separated from the inductive position sensors 8 measuring the axial displacement of the rotor 3 by an air gap J₂.

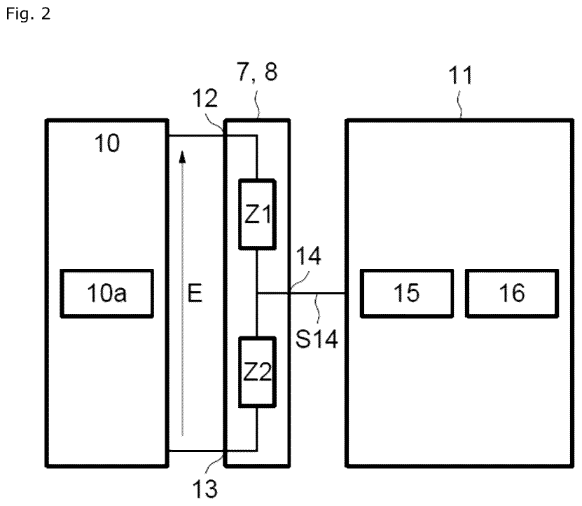

FIG. 2 shows schematically an example of a measurement assembly.

The sensor 7, 8 comprises a first impedance Z1 and a second impedance Z2.

The first impedance Z1 comprises a first end connected to a first supply terminal 12 of the sensor 7, 8 and a second end connected to a first end of the second impedance Z2.

The second impedance Z2 comprises a second end connected to a second supply terminal 13 of the sensor 7, 8.

A connection point between the second end of the first impedance Z1 and the first end of the second impedance Z2 is connected to an output terminal 14 of the sensor 7, 8.

The sensor 7, 8 supplies a measurement signal S14 at its output terminal 14.

The first and second supply terminals 12, 13 of the sensor 7, 8 are connected to the supply circuit 10 comprising an alternating voltage source 10a supplying a sinusoidal voltage E having a predetermined constant period T according to the following equation:

$$E = {E}_{0} sin ( ω t ) = {E}_{0} sin ( \frac{2 π}{T} t ) \qquad ( 1 )$$

E₀ being the amplitude of the voltage E, sin being the trigonometric sine function, t being a time variable and ω being the pulsation such that:

$$ω = \frac{2 π}{T} \qquad ( 2 )$$

The conditioning device 11 comprises a sampler 15 capable of sampling the measurement signal S14 at a first sampling time to determine a first sample of the measurement signal S14 and sampling the measurement signal S14 at a second sampling time to determine a second sample of the measurement signal, the second sampling time being separated from the first sampling time by a duration equal to one quarter of the predetermined constant period T of the sinusoidal supply voltage E.

The conditioning device 10 further comprises first means 16 suitable for breaking down the measurement signal S14 into a sum of a sine function and a cosine function from the first and second samples of the measurement signal S14, and a predetermined phase shift between the phase of the sinusoidal supply voltage E and the phase of a sampling signal associated with the first and second sampling times.

The first means 16 comprise, for example, a processing unit.

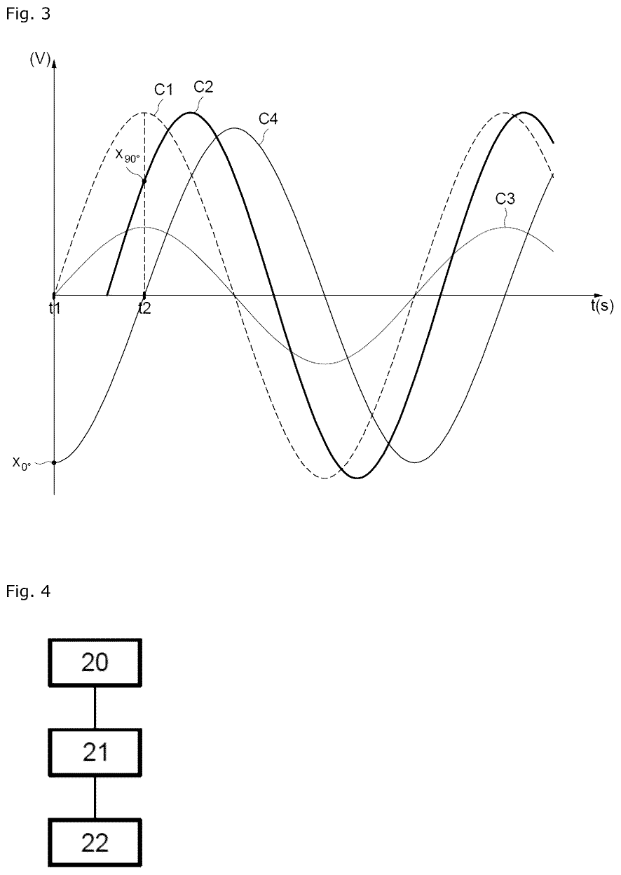

A first example of the method for conditioning the measurement signal S14 implementing the measurement assembly is now described with reference to FIGS. 3 and 4.

FIG. 3 describes a first example of the change over time in the supply voltage E and in the measurement signal S14.

In this example of the conditioning method, the measurement signal S14 is broken down by the first means 16 into a signal Sm such that:

$$Sm ( t ) = c . sin ( ω t + θ ) = a . sin ( ω t ) + b . cos ( ω t ) \qquad ( 3 )$$

where sin is the trigonometric sine function, cos is the trigonometric cosine function, t is time, ω is the pulsation according to equation (2), T is the predetermined constant period, a is a first coefficient, and b is a second coefficient, a, b, c being real numbers, and θ is a constant.

The supply voltage E is represented by a curve C1 and the measurement signal S14 modelled by the function Sm(t)=c.sin(ωt+θ) is represented by the curve C2.

The coefficient c and the constant θ are determined by identifying the signal Sm with the signal S14.

During a step 20 (FIG. 4), the sampler 15 samples the measurement signal S14 at a first sampling time t1 to determine a first sample x_{0°} of the measurement signal S14.

The first sampling time t1 is chosen when the supply voltage is zero.

The first sampling time t1 is determined by a time measuring device, for example an analog-to-digital converter.

During a step 21, the sampler 15 samples the measurement signal S14 at a second sampling time t2 to determine a second sample x_{90°} of the measurement signal S14.

The second sampling time t2 is separated from the first sampling time t1 by a duration equal to one quarter of the predetermined constant period T of the sinusoidal supply voltage E, when the absolute value of the sinusoidal supply voltage E is maximum.

During a step 22, the first means 16 break down the measurement signal S14 according to equation (3) from the first and second samples x_{0°}, x_{90°} of the measurement signal S14.

The first and second coefficients a and b are such that:

$$a = {x}_{90 °} \qquad ( 4 )$$

$$b = {x}_{0 °} \qquad ( 5 )$$

The in-phase component of the signal S14 corresponding to the function a.sin(ωt) is represented in FIG. 3 by the curve C3 and the quadrature component corresponding to the cosine function b.cos(ωt) is represented in FIG. 3 by the curve C4.

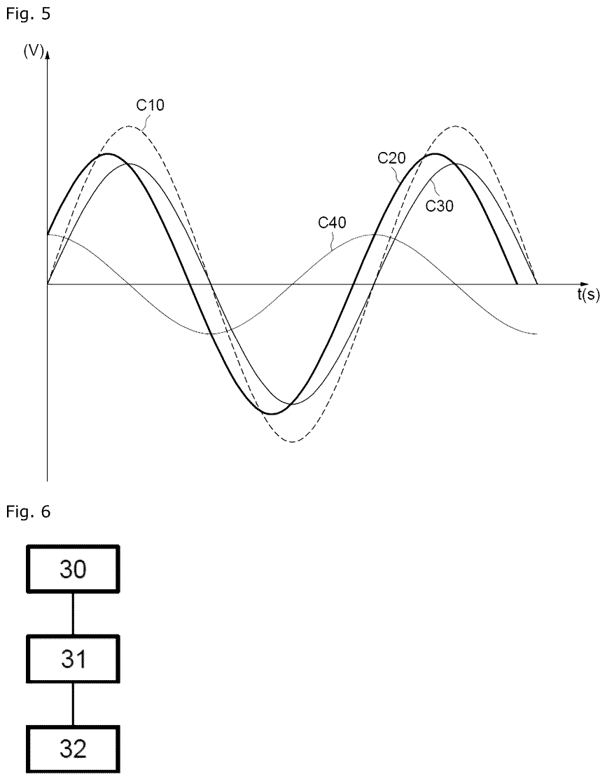

A second example of the method for conditioning the measurement signal S14 implementing the measurement assembly 11 is now described with reference to FIGS. 5 and 6.

FIG. 5 describes a second example of the change over time in the supply voltage E and in the measurement signal S14.

In this example of the conditioning method, the first sampling and the supply voltage E are phase-shifted by a constant predetermined phase shift φ.

The measurement signal S14 is broken down by the first means 16 into a signal Sm such that:

$$Sm = c . sin ( ω t + θ ) = a . sin ( ω t ) + b . cos ( ω t ) \qquad ( 6 )$$

where sin is the trigonometric sine function, cos is the trigonometric cosine function, t is time, ω is the pulsation according to equation (2), T is the predetermined constant period, a is a first coefficient, and b is a second coefficient, a, b, c being real numbers, and θ is a constant.

The supply voltage E is represented by a curve C10 and the measurement signal S14 modelled by the function Sm(t)=c.sin(ωt+θ) is represented by the curve C20. The coefficient c and the constant θ are determined by identifying the signal Sm with the signal S14.

During a step 30 (FIG. 6), the sampler 15 samples the measurement signal S14 at a first sampling time t10 to determine a first sample xₜ₁₀ of the measurement signal S14.

During a step 31, the sampler 15 samples the measurement signal S14 at a second sampling time t20 to determine a second sample xₜ₂₀ of the measurement signal S14.

The second sampling time t20 is separated from the first sampling time t10 by a duration equal to one quarter of the predetermined constant period T of the sinusoidal supply voltage E.

During a step 32, the first means 16 break down the measurement signal S14 according to equation (6) from the first and second samples xₜ₁₀, xₜ₂₀ of the measurement signal S14.

The first and second coefficients a and b are such that:

$$a = \{ \begin{matrix}cos ( {tan}^{- 1} ( \frac{{x}_{t 10}}{{x}_{t 20}} ) - φ ) \sqrt{{x}_{t 1}^{2} + {x}_{t 2}^{2}} , {x}_{t 20} \geq 0 \\ cos ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix} \qquad ( 7 )$$

$$b = \{ \begin{matrix}sin ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ sin ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix} \qquad ( 8 )$$

tan⁻¹ being the trigonometric arc tangent function.

The in-phase component of the signal S14 corresponding to the function a.sin(ωt) is represented in FIG. 5 by the curve C30 and the quadrature component corresponding to the cosine function b.cos(ωt) is represented in FIG. 5 by the curve C40.

The conditioning method makes it possible to break down the measurement signal into an in-phase component corresponding to the sine function and into a quadrature component corresponding to the cosine function.

The determination of the in-phase and quadrature components is carried out in a simple manner, without the addition of processing means or a control loop.

What is claimed is:

1. A method for conditioning a measurement signal supplied by an inductive position sensor for a rotor of an electric machine supported by at least one active magnetic bearing, the inductive position sensor measuring a displacement of the rotor and being supplied by an alternating voltage source supplying a sinusoidal supply voltage at a predetermined constant period, the method comprising:
sampling the measurement signal at a first sampling time to determine a first sample of the measurement signal,
sampling the measurement signal at a second sampling time to determine a second sample of the measurement signal, the second sampling time being separated from the first sampling time by a duration equal to one quarter of the predetermined constant period of the sinusoidal supply voltage, and
breaking down the measurement signal into a sum of a sine function and a cosine function from the first and second samples of the measurement signal and a predetermined phase shift between the phase of the sinusoidal supply voltage and the phase of a sampling signal associated with the first and second sampling times.

2. The method according to claim 1, in which the first sampling time is selected when the sinusoidal supply voltage is zero and the second sampling time is selected when the absolute value of the sinusoidal supply voltage is maximum, and the measurement signal is broken down into a signal Sm according to the following equation:
$$Sm = c . sin ( ω t + θ ) = a . sin ( ω t ) + b . cos ( ω t )$$
where sin is the trigonometric sine function, cos is the trigonometric cosine function, t is time, ω is such that
$$ω = \frac{2 π}{T} ,$$
T is the predetermined constant period, a is a first coefficient, and b is a second coefficient, a, b, c being real numbers, and θ is a constant,
the breakdown of the measurement signal comprises determining the first coefficient a and the second coefficient b from the first sample of the measurement signal associated with the first sampling time and from the second sample of the measurement signal associated with the second sampling time, the first and second coefficients a and b being such that:
$$a = {x}_{90 °}$$
$$b = {x}_{0 °}$$

3. The method according to claim 1, in which the second sampling time is selected one quarter of a period after the first sampling time, and the measurement signal is broken down into a signal Sm according to the following equation:
$$Sm = c . sin ( ω t + θ ) = a . sin ( ω t ) + b . cos ( ω t )$$
where sin is the trigonometric sine function, cos is the trigonometric cosine function, t is time, ω is such that
$$ω = \frac{2 π}{T} ,$$
T is the predetermined constant period, a is a first coefficient, and b is a second coefficient, a, b, c being real numbers, and θ is a constant,
the breakdown of the measurement signal comprises determining the first coefficient a and the second coefficient b from the first sample of the measurement signal associated with the first sampling time and from the second sample of the measurement signal associated with the second sampling time, the first and second coefficients a and b being such that:
$$a = \{ \begin{matrix}cos ( {tan}^{- 1} ( \frac{{x}_{t 10}}{{x}_{t 20}} ) - φ ) \sqrt{{x}_{t 1}^{2} + {x}_{t 2}^{2}} , {x}_{t 20} \geq 0 \\ cos ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$
$$b = \{ \begin{matrix}sin ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ sin ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$
tan⁻¹ being the trigonometric arc tangent function and φ being the predetermined phase shift between the first sampling time and the sinusoidal supply voltage, xₜ₁₀ being the first sample of the measurement signal and xₜ₂₀ being the second sample of the measurement signal.

4. A device for conditioning a measurement signal supplied by an inductive position sensor for a rotor of an electric machine supported by at least one active magnetic bearing, the inductive position sensor measuring a displacement of the rotor and being supplied by an alternating voltage source supplying a sinusoidal supply voltage at a predetermined constant period, the device comprising:
a sampler configured to sample the measurement signal at a first sampling time to determine a first sample of the measurement signal and to sample the measurement signal at a second sampling time to determine a second sample of the measurement signal, the second sampling time being separated from the first sampling time by a quarter of the predetermined constant period of the supply voltage and sinusoidal, and
first means configured to break down the measurement signal into a sum of a sine function and a cosine function from the first and second samples of the measurement signal, and a predetermined phase shift between the phase of the sinusoidal supply voltage and the phase of a sampling signal associated with the first and second sampling times.

5. The device according to claim 4, wherein the first means is configured to break down the measurement signal into a signal Sm according to the following equation:
$$Sm = c . sin ( ω t + θ ) = a . sin ( ω t ) + b . cos ( ω t )$$
where sin is the trigonometric sine function, cos is the trigonometric cosine function, t is time, ω is such that
$$ω = \frac{2 π}{T} ,$$
T is the predetermined constant period, a is a first coefficient, and b is a second coefficient, a, b, c being real numbers, and θ is a constant,
the first means further being configured to determine the first coefficient a and the second coefficient b from the first sample (x_{0°}) of the measurement signal associated with the first sampling time (t1) and from the second sample (x_{90°}) of the measurement signal associated with the second sampling time (t2), the first and second coefficients a and b being such that:
$$a = {x}_{90 °}$$
$$b = {x}_{0 °}$$

6. The device according to claim 4, wherein the first means is configured to break down the measurement signal into a signal Sm according to the following equation:
$$Sm = c . sin ( ω t + θ ) = a . sin ( ω t ) + b . cos ( ω t )$$
where sin is the trigonometric sine function, cos is the trigonometric cosine function, t is time, ω is such that
$$ω = \frac{2 π}{T} ,$$
T is the predetermined constant period, a is a first coefficient, and b is a second coefficient, a, b, c being real numbers, and θ is a constant,
the first means further being configured to determine the first coefficient a and the second coefficient b from the first sample of the measurement signal associated with the first sampling time (t10) and from the second sample of the measurement signal associated with the second sampling time (t20), the first and second coefficients a and b being such that:
$$a = \{ \begin{matrix}cos ( {tan}^{- 1} ( \frac{{x}_{t 10}}{{x}_{t 20}} ) - φ ) \sqrt{{x}_{t 1}^{2} + {x}_{t 2}^{2}} , {x}_{t 20} \geq 0 \\ cos ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$
$$b = \{ \begin{matrix}sin ( {tan}^{- 1} ( \frac{{x}_{t 10}}{{x}_{t 20}} ) - φ ) \sqrt{{x}_{t 10}^{2} + {x}_{t 20}^{2}} , {x}_{t 20} \geq 0 \\ sin ( {tan}^{- 1} ( \frac{{x}_{t 10}}{{x}_{t 20}} ) + π - φ ) \sqrt{{x}_{t 10}^{2} + {x}_{t 20}^{2}} , {x}_{t 20} < 0\end{matrix}$$
tan⁻¹ being the trigonometric arc tangent function and φ being the predetermined phase shift between the first sampling time and the sinusoidal supply voltage, xₜ₁₀ being the first sample of the measurement signal and xₜ₂₀ being the second sample of the measurement signal.

7. The device according to claim 4, further comprising a processing unit configured to control the sampler such that the phase shift equals a predetermined target value.

8. The device according to claim 5, further comprising a processing unit configured to control the sampler such that the phase shift equals a predetermined target value.

9. The device according to claim 6, further comprising a processing unit configured to control the sampler such that the phase shift equals a predetermined target value.

10. A measurement assembly comprising a conditioning device according to claim 4, and an inductive position sensor connected to the conditioning device.

11. The measurement assembly according to claim 8, wherein the inductive position sensor is a radial inductive position sensor configured to measure the radial position of the rotor.

12. The measurement assembly according to claim 8, wherein the inductive position sensor is an axial inductive position sensor configured to measure the axial position of the rotor.

13. A measurement assembly comprising a conditioning device according to claim 7, and an inductive position sensor connected to the conditioning device.

14. The measurement assembly according to claim 13, wherein the inductive position sensor is a radial inductive position sensor configured to measure the radial position of the rotor.

15. The measurement assembly according to claim 13, wherein the inductive position sensor is an axial inductive position sensor configured to measure the axial position of the rotor.

16. A measurement assembly comprising a conditioning device according to claim 9, and an inductive position sensor connected to the conditioning device.

17. The measurement assembly according to claim 16, wherein the inductive position sensor is a radial inductive position sensor configured to measure the radial position of the rotor.

18. The measurement assembly according to claim 16, wherein the inductive position sensor is an axial inductive position sensor configured to measure the axial position of the rotor.
